(19) United States
(12) Patent Application Publication
(10) Pub. No.: US 2015/0024597 A1
(43) Pub. Date: Jan. 22, 2015

(54) METHOD FOR SIDEWALL SPACER LINE DOUBLING USING POLYMER BRUSH MATERIAL AS A SACRIFICIAL LAYER

(71) Applicant: HGST Netherlands B.V., Amsterdam (NL)

(72) Inventors: He Gao, San Jose, CA (US); Ricardo Ruiz, Santa Clara, CA (US); Lei Wan, San Jose, CA (US)

(73) Assignee: HGST Netherlands B.V., Amsterdam (NL)

(21) Appl. No.: 13/943,666

(22) Filed: Jul. 16, 2013

(51) Int. Cl. H01L 21/306

(52) U.S. Cl. CPC H01L 21/30604
USPC 438/694

(57) ABSTRACT

A method for sidewall spacer line doubling uses sacrificial sidewall spacers. A mandrel layer is deposited on a substrate and patterned into mandrel stripes with a pitch double that of the desired final line pitch. A functionalized polymer is deposited over the mandrel stripes and into the gaps between the stripes. The functionalized polymer has a functional group that reacts with the surface of the mandrel stripes when heated to graft a monolayer of polymer brush material onto the sidewalls of the mandrel stripes. A layer of etch mask material is deposited into the gaps between the polymer brush sidewall spacers to form interpolated stripes between the mandrel stripes. The polymer brush sidewall spacers are removed, leaving on the substrate a pattern of mandrel stripes and interpolated stripes with a pitch equal to the desired final line pitch. The stripes function as a mask to etch the substrate.

### BACKGROUND OF THE INVENTION

1. Field of the Invention

This invention relates to line density multiplication in the area of nanotechnology, such as the fabrication of semiconductor devices and nanoimprint templates.

2. Description of the Related Art

Current photolithography has reached fundamental printing limits. One process that is gaining recognition for use in DRAM and NAND flash manufacturing is sidewall spacer “line doubling”, sometimes also referred to as “line multiplication”, “frequency doubling”, “self-aligned double patterning (SADP)”, “sidewall image transfer” or “pitch-halving”. The process also has application in making imprint templates, which may be used for making bit-patterned-media (BPM) magnetic recording disks. For example, U.S. Pat. No. 7,758,981 B2 which is assigned to the same assignee as this application, describes a method using sidewall spacer line doubling to make an imprint template with generally radial lines.

The process uses sidewall spacers to create patterned hardmasks as a means of doubling the line density. The prior art process is illustrated in FIGS. 1A-1F. A layer of hardmask material is deposited on a substrate, and a layer of mandrel material (which may be a photoresist) is patterned into lines on the hardmask layer (FIG. 1A). A conformal layer of spacer material is deposited on the tops and sides of the mandrel lines and on the hardmask layer in the gaps between the mandrel lines (FIG. 1B). The spacer material is typically formed of an inorganic material, typically oxides like Al₂O₃. The spacer material on the tops of the mandrel lines and in the gaps between the mandrel lines is then removed by anisotropic etching, leaving the mandrel lines with sidewalls of spacer material (FIG. 1C). The material of the mandrel lines is then removed, leaving lines of sidewall spacer material on the hardmask layer (FIG. 1D). The number of spacer lines in FIG. 1D is double the number of mandrel lines in FIG. 1A, and thus the pitch of the spacer lines is half the pitch of the mandrel lines, hence the terms “line doubling” and “pitch halving”. The spacer lines are then used as an etch mask to transfer the pattern into the hardmask (FIG. 1E) and the spacer lines are then removed, leaving a pattern of hardmask lines on the substrate (FIG. 1E).

Atomic layer deposition (ALD) is the typical method of depositing the inorganic oxide spacer material to achieve dimensions below about 20 nm. ALD is a thin film deposition process that is based on the sequential use of a gas phase chemical process, in which by repeatedly exposing gas phase chemicals known as the precursors to the growth surface and activating them at elevated temperature, a precisely controlled thin film is deposited in a conformal manner. ALD is a rather expensive process mostly because of the expensive precursors required. Also, the etching of the inorganic spacer material with dimensions less than 20 nm is difficult because the etching of inorganic materials often causes redeposition into the narrow trenches. The etching selectivity between inorganic materials is lower than that between inorganic and organic material.

An additional problem with the prior art method of line doubling is that the sidewall spacers formed on the mandrel stripes are used as the final etch mask to etch the substrate. However, the mandrel stripes are often not precisely perpendicular to the substrate, resulting in tilted sidewall spacers and degraded etched substrates

What is needed is a sidewall spacer line doubling process that does not require inorganic materials for the spacer material, does not rely on the spacer material as the etch mask, and does not require ALD.

### SUMMARY OF THE INVENTION

Embodiments of the invention relate to a method to double the line frequency of a lithographic process using sacrificial sidewall spacers. A mandrel layer is deposited on a substrate and lithographically patterned and etched to form a pattern of mandrel stripes with a pitch double that of the desired final line pitch. A functionalized polymer is deposited over the mandrel stripes and into the gaps between the stripes. The functionalized polymer has a functional group that reacts with the surface of the mandrel stripes when heated to graft a monolayer of polymer brush material onto the sidewalls of the mandrel stripes. The thickness of the polymer brush monolayer is selected and can be adjusted by the chemistry and molecular weight of the functionalized polymer. A layer of etch mask material is then deposited into the gaps between the polymer brush sidewall spacers to form interpolated stripes between the mandrel stripes. The polymer brush sidewall spacers are then removed, leaving on the substrate a pattern of mandrel stripes and interpolated stripes with a pitch equal to the desired final line pitch. The mandrel stripes and interpolated stripes can function as an etch mask to etch the substrate. After removal of the mandrel stripes and interpolated stripes, the substrate will have a pattern of lines with a pitch half that of the pitch of the initial mandrel stripes, i.e., with the number of lines being doubled from the number of initial mandrel stripes.

For a fuller understanding of the nature and advantages of the present invention, reference should be made to the following detailed description taken together with the accompanying figures.

### BRIEF DESCRIPTION OF THE DRAWING

FIGS. 1A-1F are sectional views illustrating the general concept of sidewall spacer line doubling according to the prior art.

FIGS. 2A-2I are sectional views illustrating an embodiment of the method for doubling the line frequency using sacrificial spacers according to the invention.

FIGS. 3A-3G are sectional views illustrating an embodiment of the method for forming the interpolated stripes between the sidewall spacers according to the invention.

FIG. 4A is a scanning electron microscopy (SEM) image of a sectional view of the mandrel stripes as depicted in FIG. 2B.

FIG. 4B is a SEM image of a sectional view of the mandrel stripes after grafting of the polymer brush material as depicted in FIG. 2D.

FIG. 4C is a SEM image of a sectional view of the mandrel stripes after grafting of the polymer brush material and after deposition of a layer of Cr.

FIG. 4D is a SEM image of a sectional view of the mandrel stripes and interpolated Cr stripes as depicted in FIG. 3G.

FIG. 4E is a SEM image of a top view of a portion of the mandrel stripes and interpolated Cr stripes as depicted in FIG. 3G.

### DETAILS OF THE INVENTION

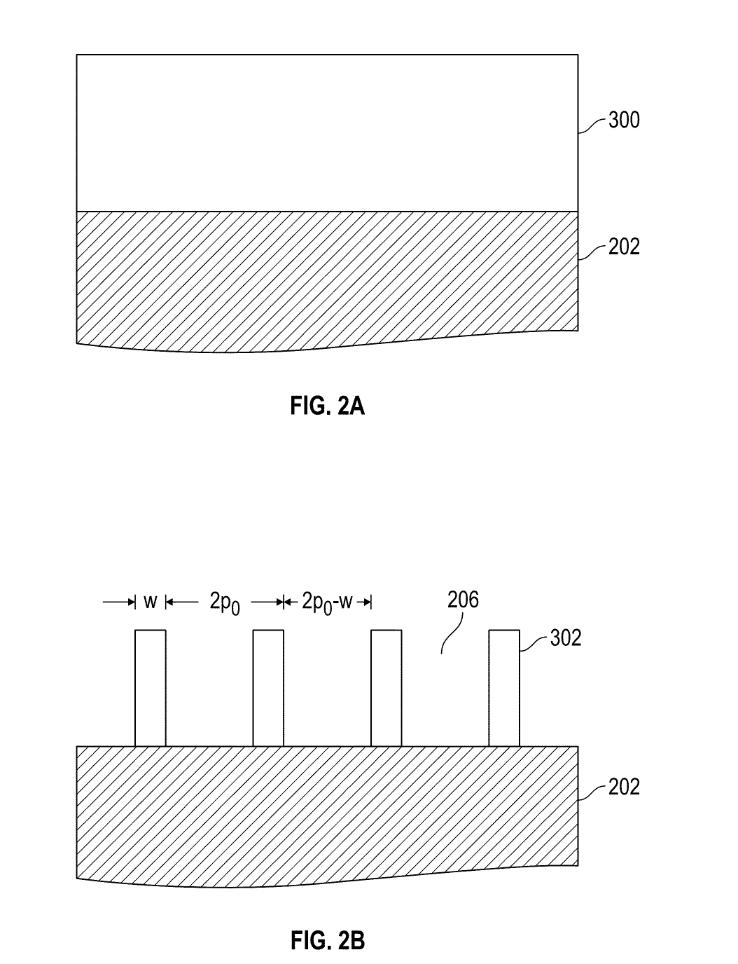

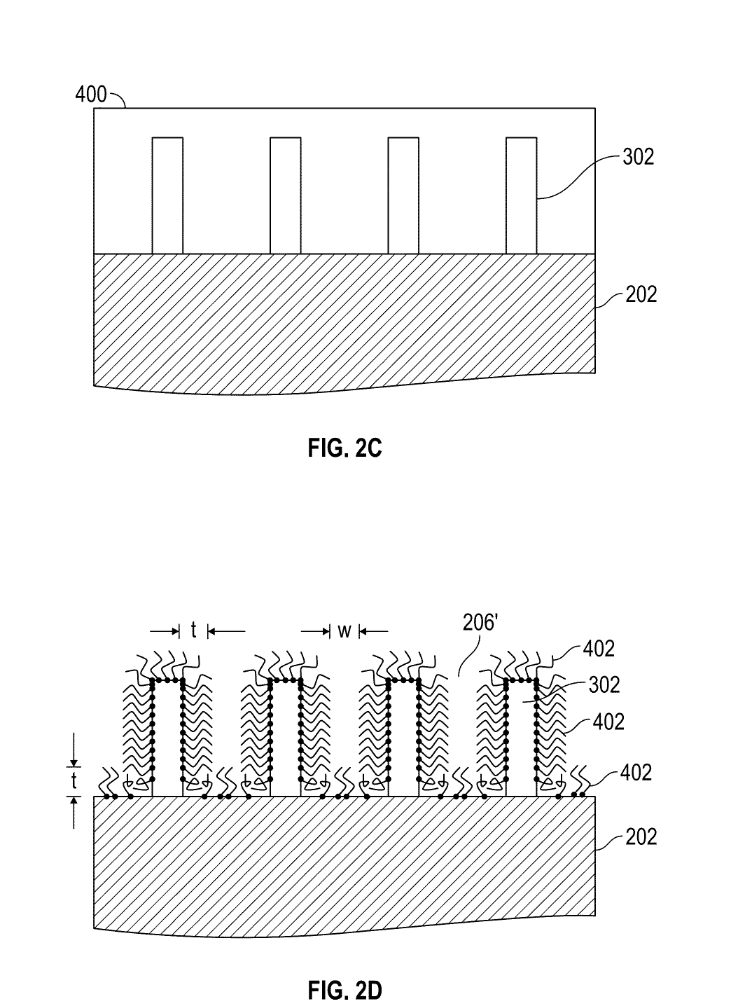

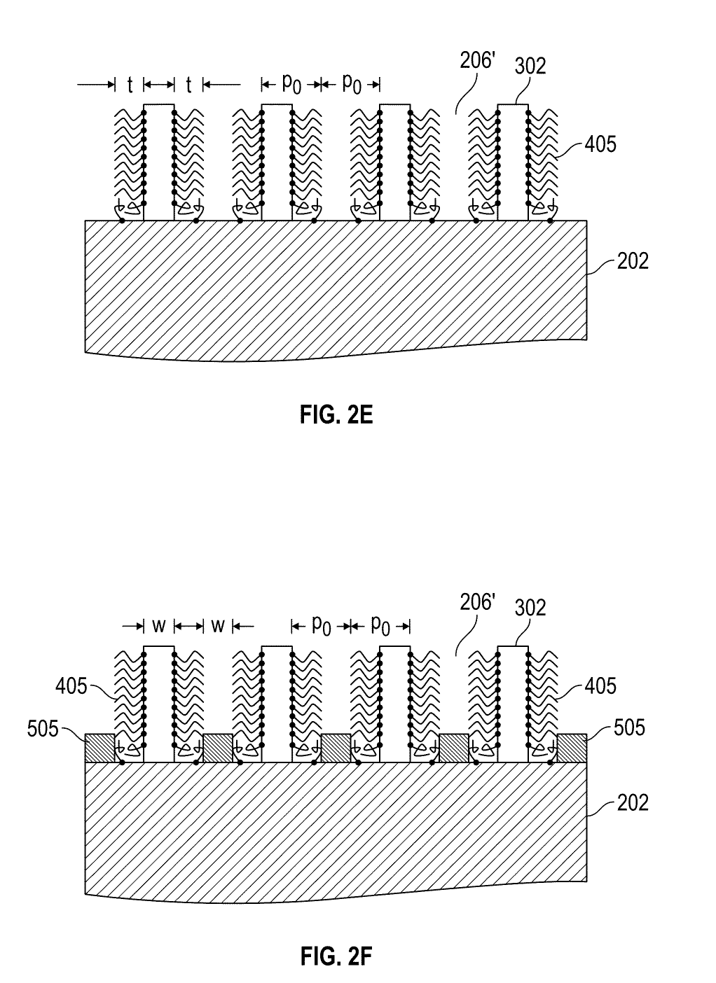

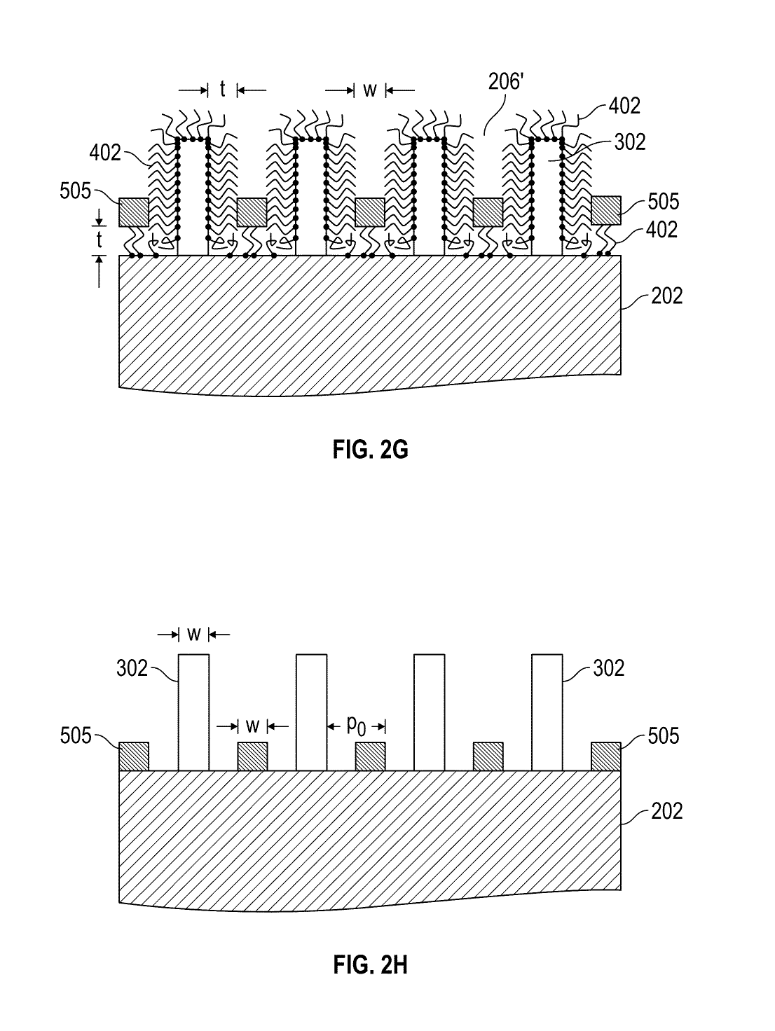

Embodiments of this invention relate to methods to double the frequency of a lithographic process using sacrificial sidewall spacers. The method starts with a mandrel layer that is patterned into a plurality of stripes with tops and sidewalls. However, instead of depositing a layer of inorganic oxide as spacer material, a monolayer of polymer brush is grafted conformably onto the mandrel stripes. Additional stripes will be added between the spacers. After removing the polymer brush spacer material, preferably by oxygen reactive ion etching (RIE), the remaining mandrel stripes and the interpolated stripes will be the final line features that double the line frequency from the initial mandrel lines. The method will be described with FIGS. 2A-2I.

Referring to FIG. 2A, the method starts with a planar substrate 202 which may be, but is not limited to, a single-crystal Si wafer, a fused silica wafer or fused quartz, and which may also be coated with materials such as silicon nitride, diamond-like carbon (DLC), tantalum, molybdenum, chromium, alumina or sapphire. A mandrel layer 300 is deposited on substrate 202. The material of the mandrel layer 300 is preferably a silicon oxide like SiO₂, but can also be silicon nitride, amorphous or polycrystalline silicon, Au, a metal oxide, or DLC. The material of the mandrel layer must be resistant to the etch chemistry used to etch the material of substrate 202. The thickness of the mandrel layer 300 is typically greater than p₀, where p₀ is to be the pitch of the final pattern of stripes. Additional layers of material (not shown), such as a resist or block copolymer and/or a hardmask material such as chromium (Cr), carbon, SiO₂ or SiNx, may be deposited on top of the mandrel layer 300 for the initial patterning to allow the lithography and transfer etching into the mandrel layer 300 in the next step. In the present example the substrate 202 is single-crystal semiconductor Si, and the mandrel layer 300 is 30 nm of SiO₂.

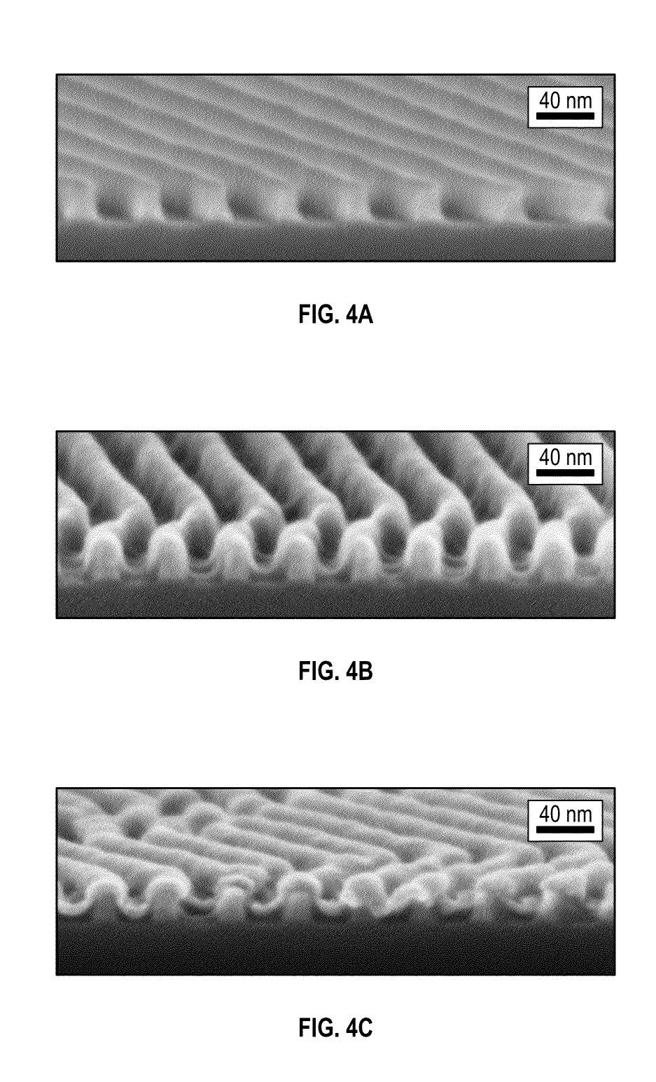

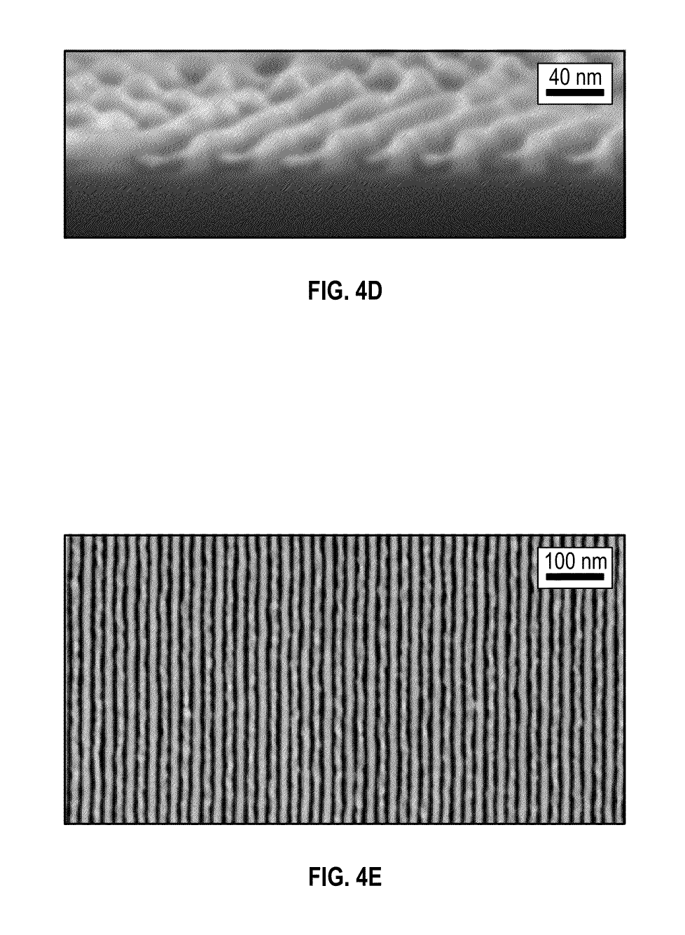

In FIG. 2B the mandrel layer 300 is patterned into periodic stripes 302. The patterning of the mandrel stripes 302 may be achieved using e-beam lithography, optical lithography, imprint lithography, directed self assembly of block copolymers, a spatial line frequency doubling process, or a combination thereof, and related etch techniques. The pitch of the periodic stripes 302 in the direction parallel to the substrate surface and orthogonal to the stripes, is 2 p₀, i.e., two times the final pitch of the stripes. The width (w) of the stripes 302 must be less than the final pitch p₀. The choice of the width (w) is typically close to p₀/2, i.e., half of the final pitch of the stripes. After patterning of the mandrel stripes 302, portions of the underlying substrate 202 are exposed in the spaces or gaps 206 between the stripes 302. The width of the gaps 206 at this step is 2 p₀−w, the difference between two times the final pitch p₀ and the stripe width w. In the present example, the desired final pitch of the stripes is approximately 20 nm, and therefore the pitch of the mandrel stripes 302 is 40 nm. The width w of the mandrel stripes 302 in the present example is approximately 14 nm. The initial patterning of the mandrel layer 300 is done using directed self-assembly of a block copolymer polystyrene-block-polymethylmethacrylate (PS-b-PMMA), followed by etching into the mandrel layer 300. FIG. 4A is a scanning electron microscopy (SEM) image of a sectional view of the mandrel stripes as depicted in FIG. 2A. The stripes 302 may be patterned as parallel generally straight stripes if the resulting etched substrate is to be used in a semiconductor device. The stripes 302 may be patterned as either generally radial stripes or generally concentric circular stripes if the resulting etched substrate is to be used as an imprint mold for making bit-patterned-media (BPM) magnetic recording disks.

Next in FIG. 2C a layer of functionalized polymer 400 is coated to fully cover the stripes 302 and into the gaps 206 between the stripes 302. The functionalized polymer contains at least one functional group to react with the material of stripes 302. The functional group is preferably a hydroxyl group, but may also be an amino group, a carboxyl group, a silane group, or a thiol group. The position of the functional group regarding the polymer chain is preferably at the end of the chain. The main chain of the polymer can be any that is vulnerable to at least one of the common etch chemistries, preferably oxygen reactive ion etching (RIE). Exemplary polymers include homopolymers based on polystyrene, poly (methyl methacrylate), polyphenylene, polyethylene, poly(ethylene oxide), polylactide, poly (vinyl pyridine), polydienes or copolymers comprising more than one monomers. In the present example, the functionalized polymer 400 is ω-hydroxyl terminated polystyrene.

Next, a heat process is carried out to induce the reaction of the functionalized polymer 400 with the mandrel stripes 302 to bind the functionalized polymer to the surface of stripes 302. This heat process may also induce reaction of the functionalized polymer 400 with the surface of substrate 202. The heat process is typically performed in vacuum at a temperature greater than 170° C. for more than 1 min. Then the un-reacted functionalized polymer is rinsed away by organic solvent (for example, N-methyl pyrrolidone (NMP), toluene, chlorobenzene, benzene, anisole or propylene glycol methyl ether acetate (PGMEA)). The result after these steps is shown in FIG. 2D. A monolayer of the functionalized polymer 402, also called a polymer “brush”, with a uniform thickness t is grafted in a conformal manner on the tops and sidewalls of stripes 302, as well as on the portions of the substrate 202 in the gaps 206. The thickness t is selected to be approximately p₀−w, the difference between the final pitch of the stripes and the width of the stripes 302. At this step, the width of the gaps 206′ is reduced to approximately w, the same as the width of the stripes 302. The thickness t of the polymer brush monolayer is selected and can be adjusted by the chemistry and molecular weight of the functionalized polymer. In the present example, the functionalized polymer is ω-hydroxyl terminated polystyrene with molecular weight of approximately 10,000 g/mol. The thickness t of the polymer brush 402 is approximately 6 nm. FIG. 4B is a SEM image of a sectional view of the mandrel stripes after grafting of the polymer brush material as depicted in FIG. 2D.

Next in FIG. 2E an anisotropic etch in a direction generally orthogonal to the substrate 202 surface is carried out to etch back the polymer brush spacer material 402 on the tops of mandrel stripes 302. The etch-back of the spacer material 402 can be done using oxygen RIE or by ion beam (Ar) etching. The height of the mandrel stripes 302 may also be shortened by the etching or ion bombardment. The etching will remove the spacer material on top of the mandrel stripes 302, and in the narrowed gaps 206′, leaving only sidewall spacers 405 of polymer brush material on the mandrel stripes 302. The lateral width of the sidewall spacers 405 is t, the thickness of the grafted polymer brush spacer material 402. The sidewall spacers 405 have a pitch of approximately p₀, the final pitch of the stripe pattern. This etch-back step is helpful for the later stripe interpolating process, but not necessary.

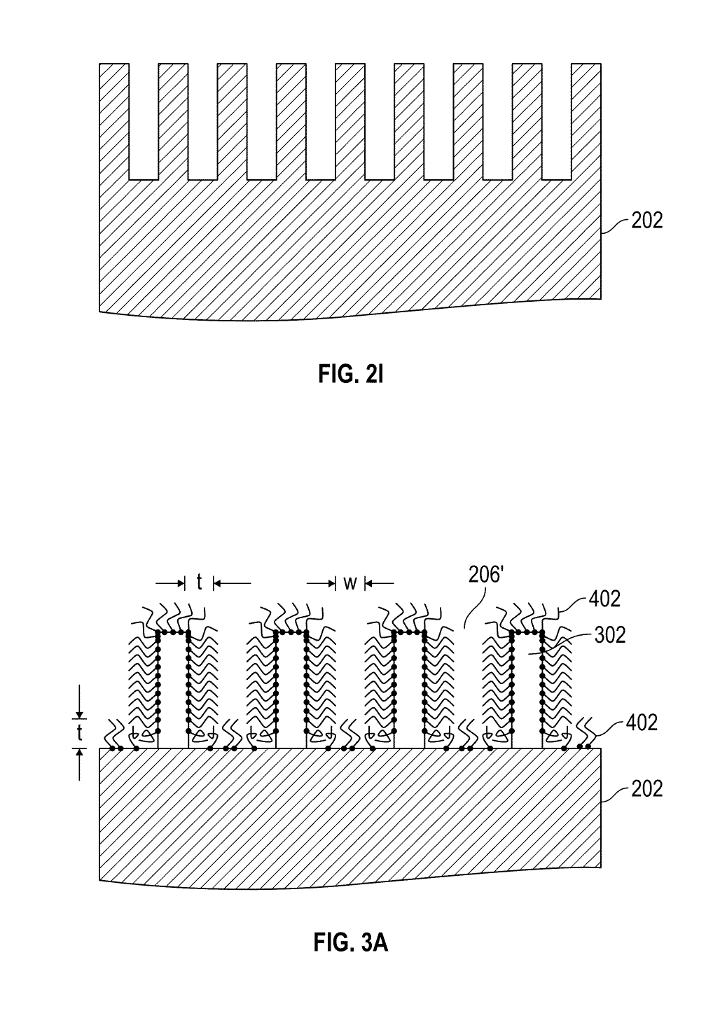

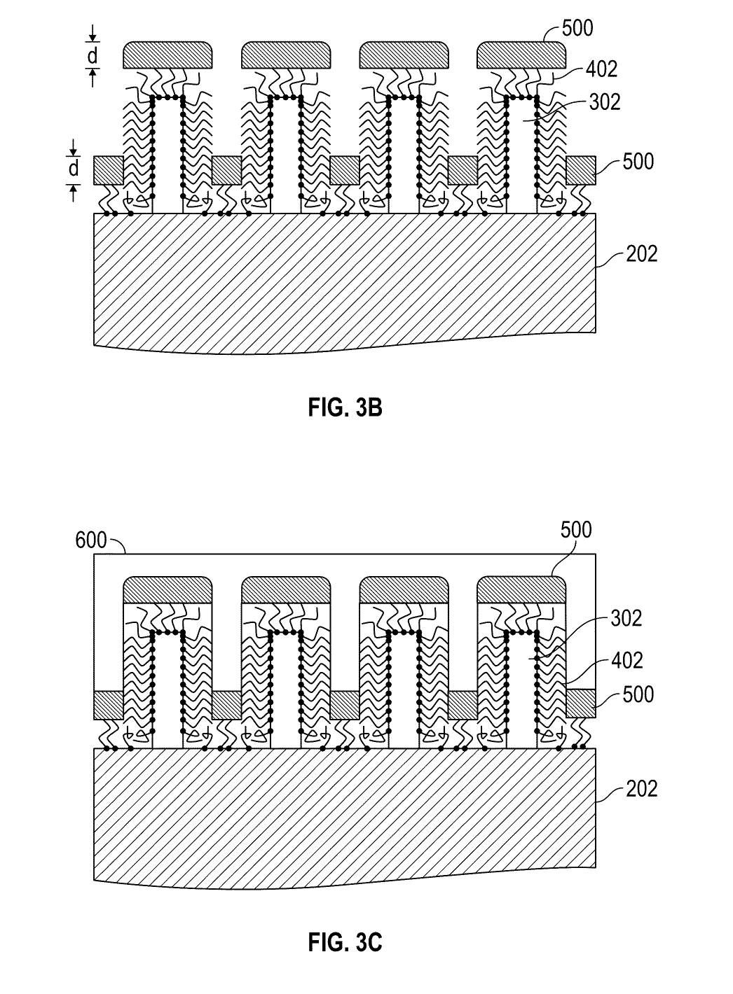

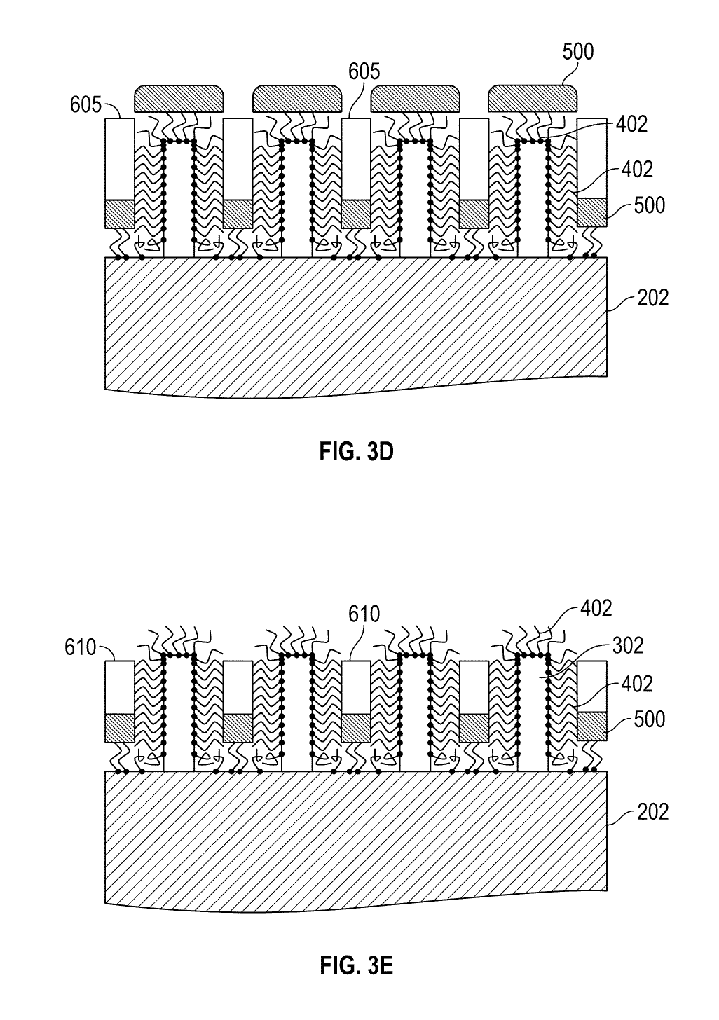

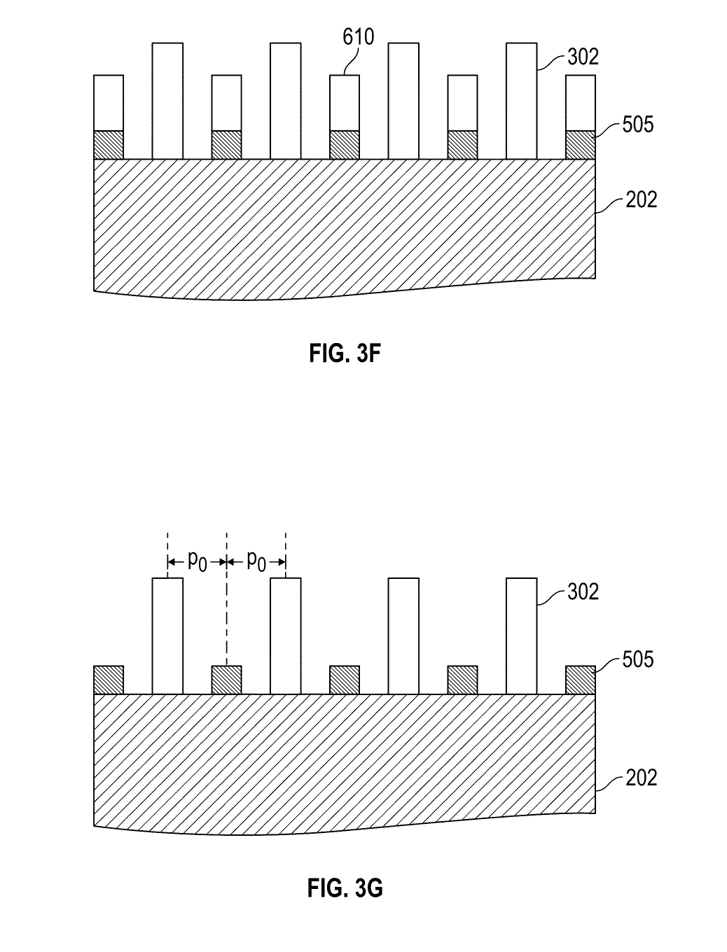

Next, as shown in either FIG. 2F or FIG. 2G, stripes 505 of etch mask material are interpolated in the gaps 206′. The interpolated stripes 505 will function as an etch mask for subsequent etching of the substrate 202 and may be formed, for example, of Cr, Mo, W, Ni, Al, Ge or an aluminum oxide (AlOₓ). In the present example the interpolated stripes are chromium (Cr). The process for forming the interpolated stripes 505 will be described below in FIGS. 3A-3G. In FIG. 2F, the interpolated stripes 505 are formed on the substrate 202 after the etch-back step of FIG. 2E. In FIG. 2G the interpolated stripes 505 are formed on the grafted polymer brush material 402 in the gaps 206′ without a prior etch-back step.

Next, as shown in FIG. 2H, an oxygen RIE etching step is performed to remove the polymer brush spacer material (405 in FIG. 2F or 402 in FIG. 2G), leaving stripe patterns comprising the mandrel stripes 302 and the interpolated stripes 505. The pitch of the final stripe patterns is p₀, and the width of both the mandrel stripes 302 and interpolated stripes 505 is approximately w. As used herein to refer to the dimensions of various widths, and thicknesses, the term “approximately” shall mean the stated dimension plus or minus 15 percent.

Next, as shown in FIG. 2I, the mandrel stripes 302 and interpolated stripes 505 can serve as the etch mask for etching the substrate 202. The etching process has to have selectivity between the material of substrate 202 and both the material of mandrel stripes 302 and the material of interpolated stripes 505. The etching is preferably by RIE or alternatively by Ar milling. For example, if the substrate 202 is Si, the mandrel stripes 302 are SiO₂ and the interpolated stripes 505 are Cr, then the etching may be by Cl₂/Ar or HBr RIE.

FIGS. 3A-3G are sectional views illustrating one method for forming the interpolated stripes 505 between the sidewall spacers 402. FIG. 3A is identical to FIG. 2D. Next, in FIG. 3B an anisotropic deposition in a direction perpendicular to the substrate 202 surface is performed to deposit a layer 500 of etch mask material to function as the interpolated stripes. The material of layer 500 is resistant to at least one etching chemistry that can etch substrate 202. In the present example, layer 500 is a Cr layer with a thickness of approximately 4 nm. FIG. 4C is a SEM image of a sectional view of the mandrel stripes 302 after grafting of the polymer brush material 402 and after deposition of a layer 500 of 4 nm thick Cr.

Next, as shown in FIG. 3C, the surface is planarized by a planarizing layer 600. In the present example, a layer of spin-on-glass (SOG) material is used for layer 600. Alternatively, the planarizing layer 600 may be formed of spin-on-carbon (SOC) or Mo, W, Ni, SiOₓ, or SiNx.

Next, in FIG. 3D, an anisotropic etch in a direction generally orthogonal to the substrate 202 surface is performed to etch back the material of planarizing layer 600. The etch-back of the planarization material can be done using RIE with an etchant gas containing fluorine and/or chlorine or by ion beam (Ar) etching. The vertical thickness of the planarization material to be removed by the etch step should be enough to reveal the underlying material of layer 500. After this etching step, the planarization material that remains is formed as stripes 605 above layer 500 in the gaps 206′.

Next, in FIG. 3E, an anisotropic etch in a direction generally orthogonal to the substrate 202 surface is performed to etch back the material of layer 500 above the mandrel stripes 302. The etch-back of the material of layer 500 can be done using RIE with an etchant gas containing fluorine and/or chlorine or by ion beam (Ar) etching. Etching selectivity between the material of layer 500 and the material of planarization stripes 605 is required. The etching ensures full removal of the material of layer 500 on top of the mandrel stripes 302 without full removal of the planarization stripes 605. The height of the planarization stripes 605 may also be shortened to stripes 610 by the etch chemistry or ion bombardment.

Next, in FIG. 3F, the polymer brush spacer material 402 in FIG. 3E can be removed by oxygen RIE. The material of mandrel stripes 302, the material of layer 500 and the planarization stripes 610 are all resistant to oxygen RIE. This leaves the stripes 302 and interpolated Cr stripes 505 with planarization stripes 610 on top of the interpolated stripes 505. Next, in FIG. 3G the remaining planarization material in stripes 610 above the interpolated Cr stripes 505 is removed by wet etching or RIE. The remaining mandrel stripes 302 and interpolated stripes 505 are the final pattern features on substrate 202 with pitch of p₀. FIG. 4D is a SEM image of a sectional view of the mandrel stripes 302 and interpolated Cr stripes 505 as depicted in FIG. 3G. FIG. 4E is a SEM image of a top view of a portion of the mandrel stripes 302 and interpolated Cr stripes 505 as depicted in FIG. 3G. The structure of FIG. 3G is then etched by Cl₂/Ar or HBr RIE, using the mandrel stripes 302 and interpolated Cr stripes 505 as an etch mask, to form the completed template as depicted in FIG. 2I.

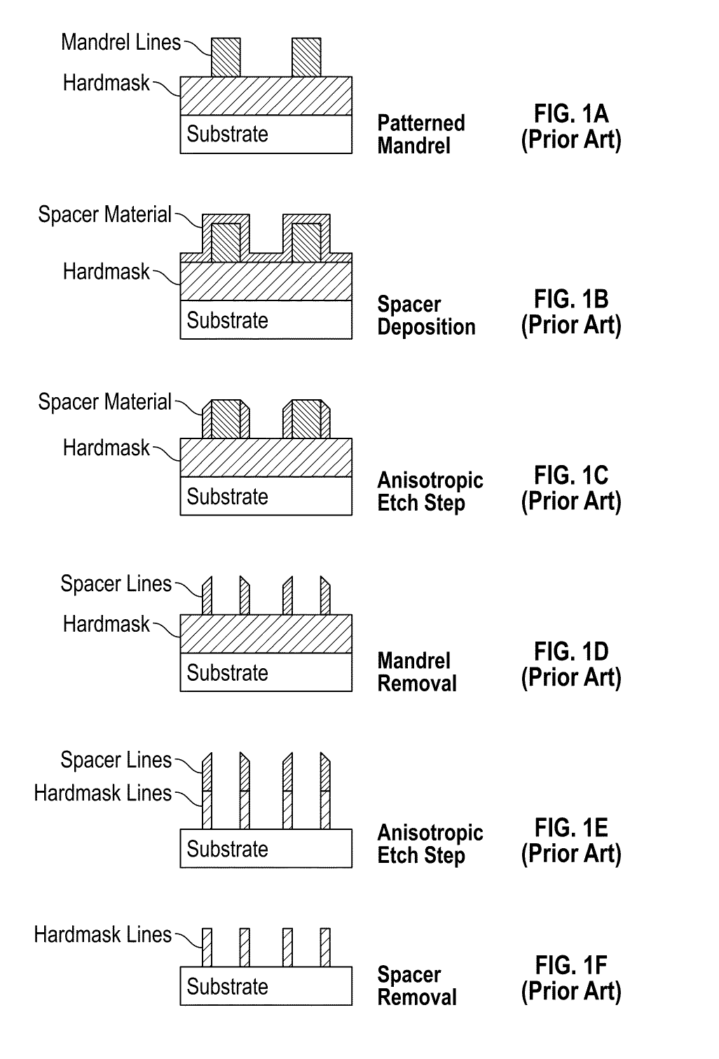

In the prior art, as shown in FIG. 1A-1F, the sidewall spacers formed on the mandrel stripes are used as the final etch mask to etch the substrate. However, the mandrel stripes are often not precisely perpendicular to the substrate, resulting in tilted sidewall spacers and degraded templates. In the present invention, the actual mandrel stripes and the interpolated stripes are used as the etch mask, so the final template shape will not affected by any tilting of the mandrel sidewalls.

While the present invention has been particularly shown and described with reference to the preferred embodiments, it will be understood by those skilled in the art that various changes in form and detail may be made without departing from the spirit and scope of the invention. Accordingly, the disclosed invention is to be considered merely as illustrative and limited in scope only as specified in the appended claims.

1. A method for making a bit-patterned media imprint mold using sidewall spacer line doubling on a substrate comprising:
providing a substrate;
depositing on the substrate a mandrel layer;
patterning the mandrel layer into a plurality of stripes selected from radial stripes and concentric circular stripes, the stripes being separated by gaps, the mandrel stripes having tops and sidewalls, a width w and a pitch 2 p₀ in a direction parallel to the substrate and orthogonal to the mandrel stripes, where w is less than p₀;
depositing a functionalized polymer over the tops and sidewalls of the mandrel stripes and into the gaps;
heating the polymer to bind the polymer to the tops and sidewalls of the mandrel stripes and to the substrate in the gaps;
removing the unbound polymer;
removing the polymer that is not bound to the tops of the mandrel stripes and to the substrate in the gaps, leaving sidewall spacers of polymer brush material having a thickness t, where t is approximately p₀−w;
depositing etch mask material on the substrate in the gaps between the sidewall spacers to form interpolated stripes having a width of approximately w on the substrate;
removing the remaining polymer brush material, leaving on the substrate a periodic pattern of mandrel stripes and interpolated stripes between the mandrel stripes having a pitch of approximately p₀, each mandrel stripe and interpolated stripe having a width of approximately w;
etching the substrate using the pattern of mandrel stripes and interpolated stripes as an etch mask to thereby form an imprint mold having a periodic pattern of recessed stripes having a pitch of approximately p₀, each recessed stripe having a width of approximately t; and
removing the mandrel stripes and interpolated stripes from the imprint mold.

2. The method of claim 1 wherein providing a substrate comprises providing a substrate selected from a Si wafer, a fused silica wafer and fused quartz.

3. The method of claim 1 wherein providing a substrate comprises providing a substrate having a coating selected from a silicon nitride, diamond-like carbon, tantalum, molybdenum, chromium, alumina and sapphire.

4. The method of claim 1 wherein depositing a mandrel layer comprises depositing a mandrel layer selected from a silicon oxide, a silicon nitride, amorphous silicon, polycrystalline silicon, Au, a metal oxide, and diamond-like carbon.

5. The method of claim 1 wherein depositing a functionalized polymer comprises depositing a homopolymer selected from polystyrene, poly (methyl methacrylate), polyphenylene, polyethylene, poly(ethylene oxide), polylactide, poly (vinyl pyridine) and polydienes and having a functionalized group selected from a hydroxyl group, an amino group, a carboxyl group, a silane group, and a thiol group.

6. The method of claim 1 wherein depositing etch mask material comprises depositing material selected from Cr, Mo, W, Ni, Ge, Al and AlOₓ.

7. The method of claim 1 wherein patterning the mandrel layer into a plurality of stripes comprises patterning the mandrel layer into a plurality of radial stripes having said pitch 2 p₀, and wherein removing the remaining polymer brush material leaves on the substrate a periodic pattern of mandrel stripes and interpolated stripes between the mandrel stripes having a pitch greater than or equal to 0.85 p₀ and less than or equal to 1.15 p₀.

8. (canceled)

9. The method of claim 1 wherein depositing the etch mask material further comprises:
depositing the etch mask material in the gaps between the sidewall spacers and on the tops of the mandrel stripes;
depositing a planarizing layer over the etch mask material in the gaps and the etch mask material on the tops of the mandrel stripes;
etching the planarizing layer in a direction substantially orthogonal to the substrate to remove the planarizing layer above the etch mask material on the tops of the mandrel stripes and a portion of the planarizing layer above the etch mask material in the gaps, leaving stripes of planarizing material above the etch mask material in the gaps; and
removing the stripes of planarizing material above the etch mask material in the gaps.

10. The method of claim 9 wherein removing the polymer brush material is performed before removing the stripes of planarizing material.

11. The method of claim 9 wherein depositing a planarizing layer comprises depositing a layer of material selected from spin-on glass, spin-on carbon, Mo, W, Ni, SiOₓ and SiNx.

12. A method for making a bit-patterned media imprint mold using sidewall spacer line doubling on a substrate comprising:
providing a substrate;
depositing on the substrate a mandrel layer formed of a silicon oxide;
patterning the mandrel layer into a plurality of stripes selected from radial stripes and concentric circular stripes, the stripes being separated by gaps, the mandrel stripes having tops and sidewalls, the mandrel stripes having a width w and a pitch 2 p₀ in a direction parallel to the substrate and orthogonal to the mandrel stripes, where w is less than p₀;
depositing a functionalized polymer over the tops and sidewalls of the mandrel stripes and into the gaps, the functionalized polymer having a hydroxyl functional group;
heating the polymer to bind the polymer to the tops and sidewalls of the mandrel stripes and to the substrate in the gaps;
removing the unbound polymer, leaving sidewall spacers of a monolayer of polymer brush material having a thickness t, where t is approximately p₀−w;
depositing etch mask material on the bound polymer in the gaps between the sidewall spacers to form interpolated stripes having a width of approximately w on the substrate;
removing the bound polymer from the tops and sidewalls of the mandrel stripes and from the substrate in the gaps,
leaving on the substrate a periodic pattern of mandrel stripes and interpolated stripes between the mandrel stripes, the mandrel stripes and interpolated stripes having a pitch in direction parallel to the substrate and orthogonal to the mandrel stripes and interpolated stripes of approximately p₀, each mandrel stripe and interpolated stripe having a width of approximately w;
etching the substrate using the pattern of mandrel stripes and interpolated stripes as an etch mask to thereby form an imprint mold having a periodic pattern of recessed stripes having a pitch of approximately p₀, each recessed stripe having a width of approximately t; and
removing the mandrel stripes and interpolated stripes from the imprint mold.

13. The method of claim 12 wherein providing a substrate comprises providing a substrate selected from a Si wafer, a fused silica wafer and fused quartz.

14. The method of claim 12 wherein providing a substrate comprises providing a substrate having a coating selected from a silicon nitride, diamond-like carbon, tantalum, molybdenum, chromium, alumina and sapphire.

15. The method of claim 12 wherein depositing a functionalized polymer comprises depositing a homopolymer selected from polystyrene, poly (methyl methacrylate), polyphenylene, polyethylene, poly(ethylene oxide), polylactide, poly (vinyl pyridine) and polydienes and having said hydroxyl group.

16. The method of claim 12 wherein depositing the etch mask material comprises depositing material selected from Cr, Mo, W, Ni, Ge, Al and AlOx.

17. (canceled)

18. (canceled)

19. (canceled)
